(19) United States
(12) Patent Application Publication
(10) Pub. No.: US 2007/0170499 A1
(43) Pub. Date: Jul. 26, 2007

(54) Semiconductor device and manufacturing method thereof

(75) Inventor: Noriaki Araki, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 11/655,986

(22) Filed: Jan. 22, 2007

(30) Foreign Application Priority Data
Jan. 23, 2006 (JP) 2006-013833

(51) Int. Cl. H01L 29/94

(52) U.S. Cl. 257/330

(57) ABSTRACT

A semiconductor device has elements formed on a substrate separately from each other. Each of the elements includes first and second regions as a source and a drain; a gate electrode formed to have a buried gate structure, and a portion of the gate electrode is put between the first and second regions. The width of the gate electrode is wider than the gate width of the first and second regions.

### BACKGROUND OF THE INVENTION

1. Field of the Invention

The present invention relates to a semiconductor device.

2. Description of the Related Art

Generally, a semiconductor device is manufactured by forming an element on a semiconductor substrate such as a silicon substrate by a lithography technique using a mask pattern. In recent years, in order to highly integrate elements of a semiconductor device, miniaturization of the element is progressed. In order to form the fine element, high precision and high definition exposure technology is needed together with a precise mask.

However, it takes a long time and a high cost for a precise mask, for the reason that the yield of the mask is low. In order to perform highly precise and high definition exposure, a long process time and an expensive apparatus are needed. Under these circumstance, a long time and a high cost have been required for manufacturing the semiconductor device with the fine elements.

Hereinafter, the formation of a conventional element will be described. A conventional method for forming the element is disclosed in Japanese Laid Open Patent Application (JP-P2004-39985A, first conventional example). Forming of NMOS according to the method described in the first conventional example will be described. FIGS. 1A and 1B are diagrams showing masks used for forming NMOS according to the first conventional example. FIG. 1C shows a state in which the masks shown in FIGS. 1A and 1B are stacked. A mask 110 shown in FIG. 1A includes diffusion region patterns 111 and 112, and an element isolating region pattern 113. A mask 120 shown in FIG. 1B includes a gate region pattern 121. As shown in FIG. 1C, in FIG. 1A and FIG. 1B, the width W10 of the diffusion region pattern 112 in the center portion of the mask 110 and the width W20 of the gate region pattern 121 are substantially identical. Further, the gate length L of the gate region pattern 121 corresponds to the minimum line width in a process, for example.

FIG. 2 shows a top view of a layout of an NMOS transistor manufactured. Here, a sectional view along the line X-X′ line and a sectional view along the line Y-Y′ line in the layout of FIG. 2 are shown in FIGS. 3A-1 to 3D-2. The manufacturing process of the NMOS in the first conventional example will be described with reference to FIGS. 3A-1 to 3D-2. It should be noted that FIGS. 3A-1 to 3D-2 show the sectional view along the line X-X′ line and the sectional view along the line Y-Y′ line of the layout of FIG. 2 for respective manufacturing process.

FIGS. 3A-1 and 3A-2 show the sectional views after the completion of a first process. Firstly, in the first process, for example, phosphorus ions are implanted into a silicon substrate 131 to form a diffusion region 132. Subsequently, element isolating trench 133 are formed by etching in which precise patterning is performed by using the mask 110. The element isolating trench 133 is formed in the region such that the silicon substrate 131 is exposed through the surface of diffusion region 132.

FIGS. 3B-1 and 3B-2 show sectional views after completion of a second process. In the second process, the element isolating trench 133 is filled with an insulating film to form the isolation region 134. After filling the element isolating trench 133 with the insulating film, the excessive insulating film on the surface of the substrate is removed.

FIGS. 3C-1 and 3C-2 show sectional views after completion of a third process. In the third process, a trench 135 for buried gate structure is formed with etching in which a precise patterning is performed by using the mask 120. The gate oxide 136 is formed in the side and the bottom of the trench 135 for the buried gate trench.

FIGS. 3D-1 and 3D-2 show the sectional views after completion of a fourth process. In the fourth process, the trench 135 for the buried gate structure, formed in the third process is filled with the gate electrode material to form the buried gate 137. After the buried gate 137 is formed, the excessive gate electrode material is removed on the substrate surface. Thus, a manufacturing process of a general NMOS in the conventional example is completed.

A technique for reducing the number of times of the precise patterning is disclosed in Japanese Laid Open Patent Application (JP-A-Heisei 7-183499, second conventional example). FIG. 4 shows a sectional view of an element in the second conventional example. In the second conventional example, an buried gate electrode region and an element isolating region are etched once by using a same mask, and each region is filled with gate oxide films 152 and 142; and gate electrode materials such as polysilicon films (poly-Si) 151 and 141. Thus, in the second conventional example, the number of the precise patterning is reduced.

In the first conventional example, since the precise patterning is needed twice, there is a problem that time and cost for manufacturing the masks 110 and 120 are increased. Further, in order to position the masks 110 and 120 highly precisely, it takes a long time and an expensive manufacturing apparatus is needed in manufacturing processes.

In the second conventional example, since the precise patterning can be achieved at a time, time and cost for masking and manufacturing processes are reduced as compared with the first conventional example. However, the element isolating region and the buried gate electrode are formed with the same polysilicon and insulating film. Therefore, in order to ensure isolation between the element isolating region and the buried gate electrode, it is necessary to reserve a predetermined distance between the element isolating region and the buried gate electrode. That is, in the second conventional example, though a trench can be formed with sufficient accuracy, variation in the boundary region of the gate electrode and the element isolating region which is formed in the trench is not taken into consideration. Therefore, in order to secure a margin for the variation in the region between the element isolating region and the buried gate electrode, it is necessary to enlarge the area for an element. This is substantial obstacle for improving an integration degree of elements.

In conjunction with the above description, a high breakdown voltage device with an insulation gate pinch off structure is disclosed in Japanese Laid Open Patent Application (JP-A-Heisei 10-190002). In this conventional example, the device includes vertical separation trenches defining an active region on the substrate with an SOI (Silicon On Insulator) structure, a vertical separation trench oxide film formed inside the vertical separation trench, a source formed in a horizontal direction in the activated region, a drift region, a drain, and a horizontal gate formed above a boundary section the drift region and the source. The device further includes a plurality of vertical trench gates formed in a predetermined interval in the substrate lower than the horizontal gate, insulated from the substrate by an oxide film and having a predetermined area.

### SUMMARY OF THE INVENTION

In an aspect of the present invention, a semiconductor device has elements formed on a substrate separately from each other. Each of the elements includes first and second regions as a source and a drain; a gate electrode formed to have a buried gate structure, and a portion of the gate electrode is put between the first and second regions. The width of the gate electrode is wider than the gate width of the first and second regions.

Here, the gate electrode may have a third portion which is not put between the first and second regions. The gate length between the first and second regions is preferably shorter than the length of the third portion in a gate length direction.

Also, the gate electrode may have a third portion which is not put between the first and second regions, and two ends of the third portion may be provided for ends in a gate width direction.

Also, each of first and second regions may be contact with an element separation region at a part of sides other than a side opposite to a side of the other.

Also, each of the first and second regions is contact with an element separation region at a whole of sides other than a side opposite to a side of the other.

Also, the elements are arranged, and the gate electrode is common to the elements and has the third portion length between the elements.

Also, the depth of the element separation region is substantially a same as that of the gate electrode.

Also, the depth of the element separation region is deeper than that of the gate electrode.

In another aspect of the present invention, a method of manufacturing a semiconductor device is achieved by forming a conductive region on a semiconductor substrate; by performing a first patterning to the conductive layer and the semiconductor substrate by using a first mask to form a gate electrode trench, a device separation trench, and first and second regions; by filling the gate electrode trench and the device separation trench with a gate electrode material; by forming a resist pattern by using a second mask having a pattern coarser than the first mask; by removing the gate electrode material from a part of the gate electrode trench and the device separation trench by the resist pattern; and by filing the gate electrode trench part and the device separation trench with an insulating film to form a device separation region.

Here, the width of the gate electrode may be wider than a width of the first and second regions in a gate width direction.

Also, the gate length between the first and second regions is preferably shorter than a length of a third portion of the gate electrode which is not put between the first and second regions, in a gate length direction.

Also, the depth of the device separation region may be substantially a same as that of the gate electrode, or may be deeper than that of the gate electrode.

Also, the method may be achieved by further forming a gate oxide film on a bottom and side wall of the gate electrode trench and the device separation trench, before filling the gate electrode material into the gate electrode trench and the device separation trench.

In another aspect of the present invention, a method of manufacturing a semiconductor device, is achieved by forming a conductive region on a semiconductor substrate; by performing a first patterning to the conductive layer and the semiconductor substrate by using a first mask to form a gate electrode trench, a device separation trench, and first and second regions; by filling the gate electrode trench and the device separation trench with an insulating film to form a device separation region; by forming a resist pattern by using a second mask having a pattern coarser than the first mask, to expose a part of the gate electrode trench and a periphery of the gate electrode trench; by removing the insulating film from a region not covered by the resist pattern; and by filling a gate electrode material in a region from which the insulating film is removed, to form a gate electrode.

Here, the width of the gate electrode may be wider than a width of the first and second regions in a gate width direction.

Also, the gate length between the first and second regions is preferably shorter than a length of a third portion of the gate electrode which is not put between the first and second regions, in a gate length direction.

Also, the depth of the device separation region may be substantially a same as that of the gate electrode, or may be deeper than that of the gate electrode.

Also, the method may be achieved by further forming a gate oxide film on a bottom and side wall of the gate electrode trench and the device separation trench, before filling the gate electrode material into the gate electrode trench and the device separation trench.

According to the semiconductor device and the manufacturing method thereof of the present invention, it becomes possible to form the shape of a gate electrode and the shape of an MOS transistor defined in a fine pitch, with reducing the number of times of a highly precise and high definition exposure process, and with reducing the number of masks having a highly precise pattern.

### BRIEF DESCRIPTION OF THE DRAWINGS

FIGS. 1A and 1B are diagrams showing masks used for manufacturing a MOS transistor;

FIG. 1C is a diagram showing a state in which the masks shown in FIGS. 1A and 1B are overlapped;

FIG. 2 shows a top view of a layout of a conventional MOS transistor;

FIGS. 3A-1 to 3D-2 are sectional views a semiconductor device of a first conventional example along the line X-X′ and line Y-Y′ shown in FIG. 2;

FIG. 4 is a sectional view showing an element in a second conventional example;

FIGS. 5A and 5B are diagrams showing masks;

FIG. 5C is a diagram showing a state in which the masks shown in FIGS. 5A and 5B are overlapped;

FIG. 6 is a top view showing a layout of a MOS transistor formed by using the masks shown in FIGS. 5A and 5B;

FIGS. 7A-1 to 7E-2 are sectional views a semiconductor device of a first embodiment of the present invention along the line X-X′ and line Y-Y′ shown in FIG. 6;

FIG. 8 is a top view showing a layout of the MOS transistor of a second embodiment of the present invention;

FIGS. 9A-1 to 9E-2 are sectional views a semiconductor device of the second embodiment of the present invention along the line X-X′ and line Y-Y′ shown in FIG. 8;

FIG. 10 is a top view showing a layout of the MOS transistor of a third embodiment of the present invention;

FIGS. 11A-1 to 11E-2 are sectional views a semiconductor device of the third embodiment of the present invention along the line X-X′ and line Y-Y′ shown in FIG. 10;

FIGS. 12A and 12B are diagrams showing masks used in forming a SRAM memory cell according to a fourth embodiment of the present invention;

FIG. 12C is a diagram showing a state in which the masks shown in FIGS. 12A and 12B are overlapped;

FIG. 13 is a top view showing a layout of the SRAM memory cells formed by using the masks; and

FIG. 14 is a circuit diagram of the SRAM according to the fourth embodiment.

### DESCRIPTION OF THE PREFERRED EMBODIMENTS

Hereinafter, a semiconductor device of the present invention will be described in detail with reference to attached drawings.

### First Embodiment

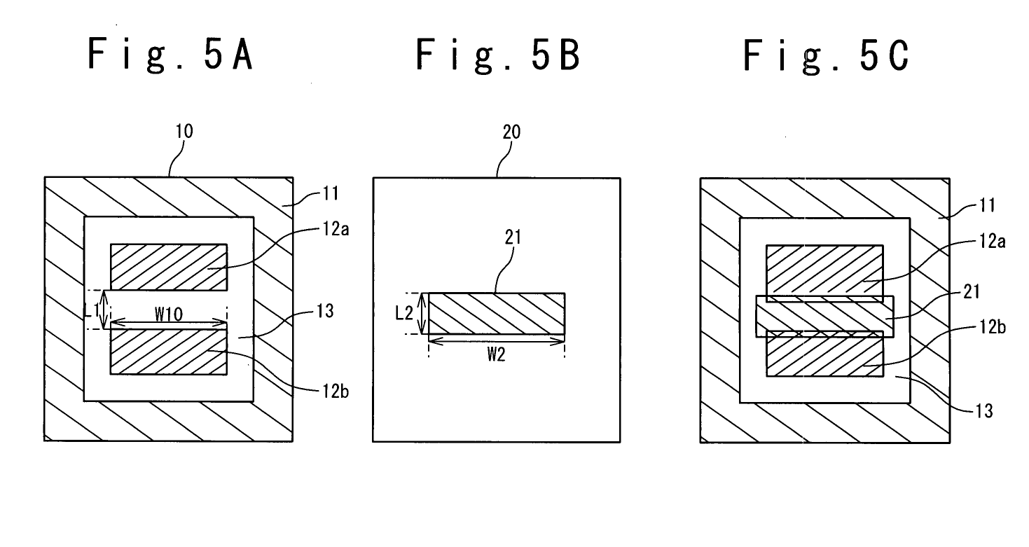

The semiconductor device according to the first embodiment of the present invention has an element formed in a fine process. As an example of the formed element, the formation of an MOS transistor is described below. FIGS. 5A to 5C show simplified diagrams of a mask used in forming a single MOS transistor.

A mask 10 shown in FIG. 5A includes diffusion region patterns 11, 12a, and 12b, and a trench region pattern 13. Further, the mask 10 is a highly precise mask which has a pitch pattern finer than other masks. The diffusion region pattern 11 is a pattern for forming a diffusion region surrounding the element to be formed, for example. The diffusion region patterns 12a and 12b are patterns for forming the diffusion regions for a source region and a drain region in an MOS transistor to be formed. In the present embodiment, the diffusion region patterns 12a and 12b serve as first and second regions which are separated from each other. The first region serves as the source region, and the second region serves as a drain region. The trench region pattern 13 is a pattern for forming an element isolating trench for an element isolating region in the outer periphery of the element to be formed, and for forming a trench for a gate electrode to be formed.

A mask 20 shown in FIG. 5B has a gate region pattern 21. The mask 20 is inferior in precise to the mask 10, and has a pitch pattern coarser than that of the mask 10. The gate region pattern 21 is protects gate electrode material from etching, in case that the gate electrode material of an element is once deposited and removed through the etching. The gate electrode material remaining after the etching serves as a gate electrode of the element. The gate region pattern 21 includes a portion for a trench portion for the gate electrode and a portion of the periphery of the gate electrode trench.

FIG. 5C shows a pattern in which the mask 10 and mask 20 are overlapped. As shown in FIG. 5C, the width W1 in a direction along the diffusion region pattern 12a and 12b in the mask 10 is shorter than the width W2 in a longitudinal direction of the gate region pattern 21 in the mask 20. The width W1 defines the gate width of the transistor. Further, a distance L1 between the diffusion region patterns 12a and 12b in the mask 10 opposing to each other is shorter than a length L2 of the gate region pattern 21 in the mask 20 along a lateral direction. In the present embodiment, the distance L1 corresponds to the minimum line width in a process rule. The gate length of a transistor is set based on the distance L1.

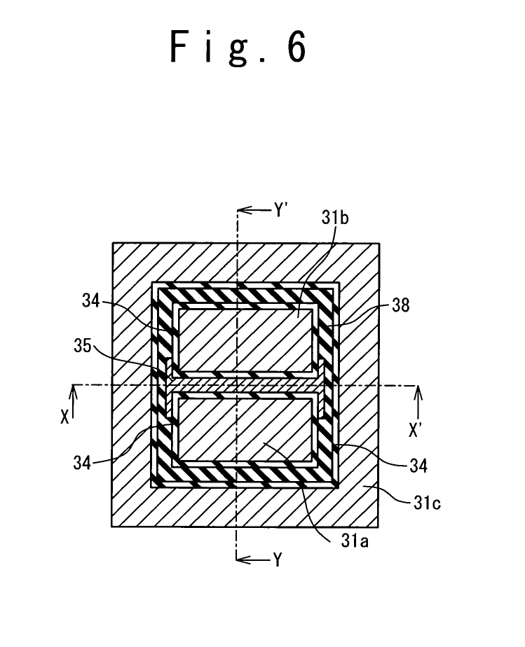

FIG. 6 a top view showing a layout of an MOS transistor formed by using the masks shown in FIGS. 5A and 5B. In the present embodiment, the gate width direction along the line X-X′ in FIG. 6 is defined as a first direction, and the gate length direction along the line Y-Y′ is defined as a second direction. The MOS transistor shown in FIG. 6 includes diffusion regions 31a and 31b, a gate electrode 35, a gate oxide film 34, and an element isolating region 38.

The diffusion regions 31a and 31b have two regions separated from each other. The separated regions are located along the second direction. The diffusion regions 31a and 31b are formed as rectangular shapes longer in a first direction, and the width in the first direction is W1. Along the outer periphery of the diffusion regions 31a and 31b, gate oxide films 34 are formed.

The gate electrode 35 is formed to be adjacent to each of the diffusion regions 31a and 31b which are formed separately from each other, through the gate oxide 34. The length between the diffusion region 31a and the diffusion region 31b in the gate electrode 35 in the gate length direction is shorter than the length of a third region, i.e., the length of a region other than a region between the diffusion region 31a and the region 31b in the gate electrodes 35 in the gate length direction. In the present embodiment, both ends of the gate electrode 35 along the gate width direction are formed to have a T-shape. Further, a portion of the gate electrode 35 adjacent to the opposing sides of separated diffusion regions 31a and 31b serves as a gate in operation of the transistor.

The element isolating region 38 is formed to surround the diffusion regions 31a and 31b, the gate oxide film 34, and the gate electrode 35. The element isolating region 38 is formed of insulator, to isolate the adjacent elements from each other. Further, the oxide film 34 is formed along the outer periphery of the element isolating region 38. Further, the diffusion region 31c is formed in the outer periphery of the element isolating region 38 and the oxide film 34.

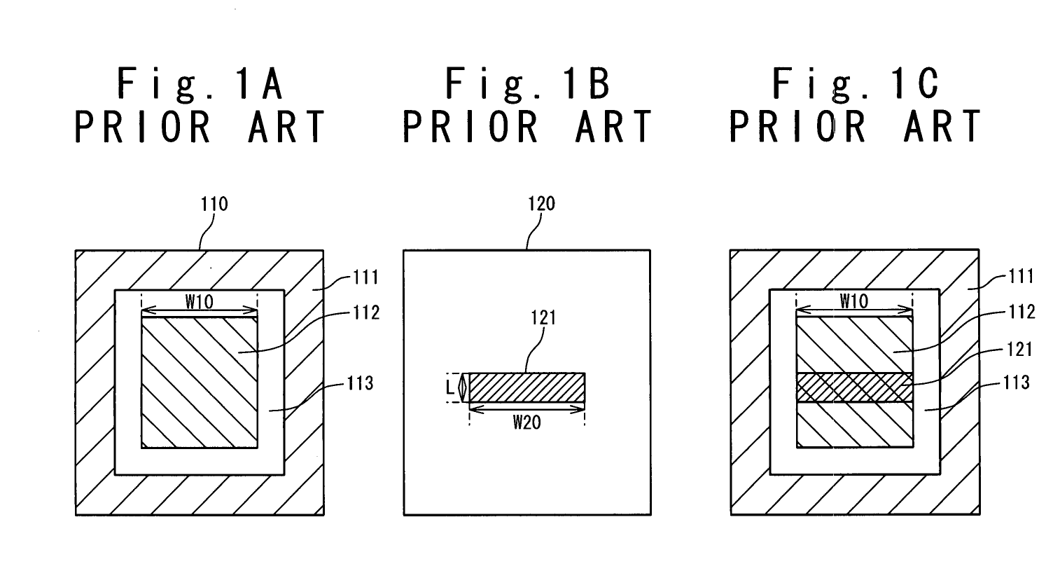

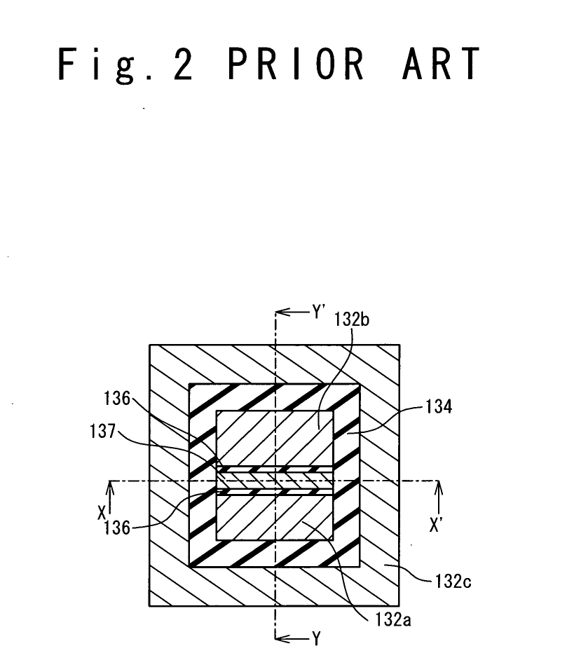

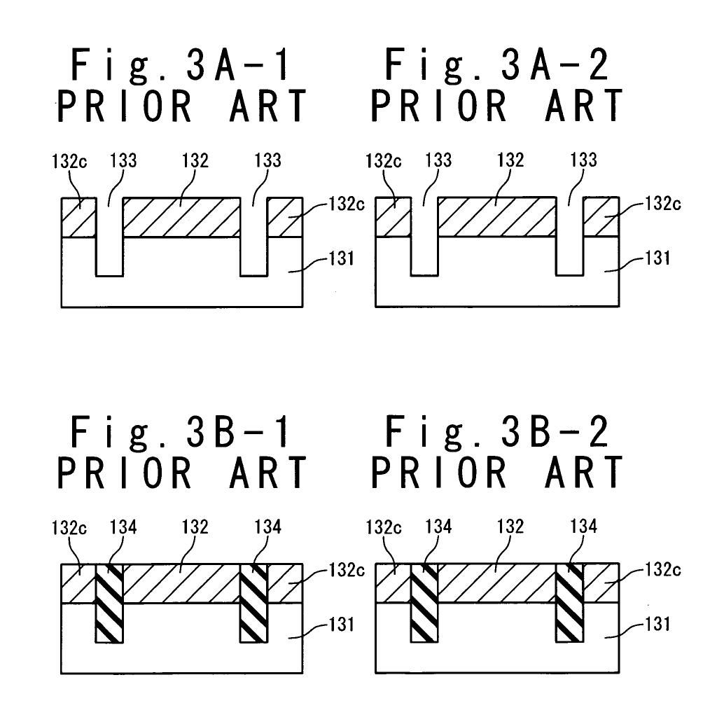

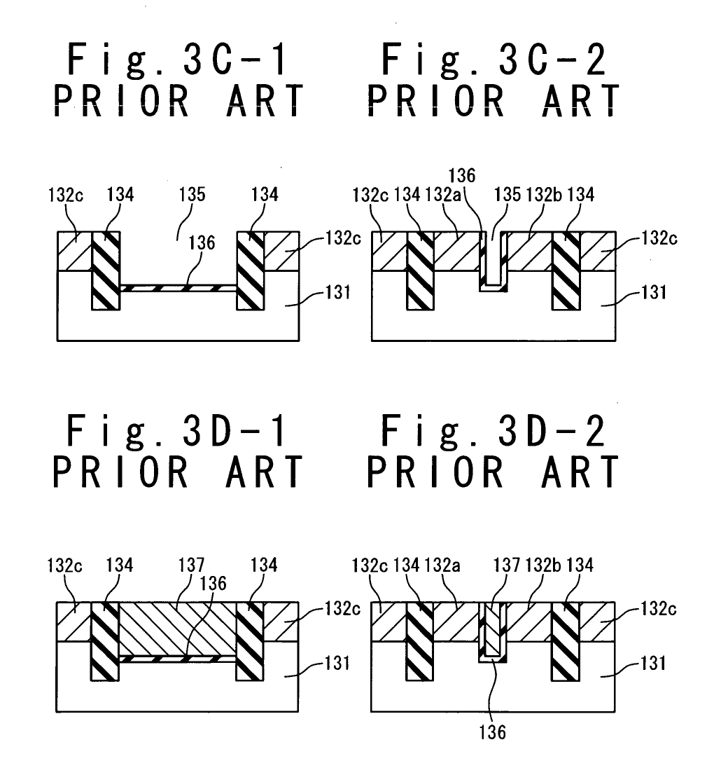

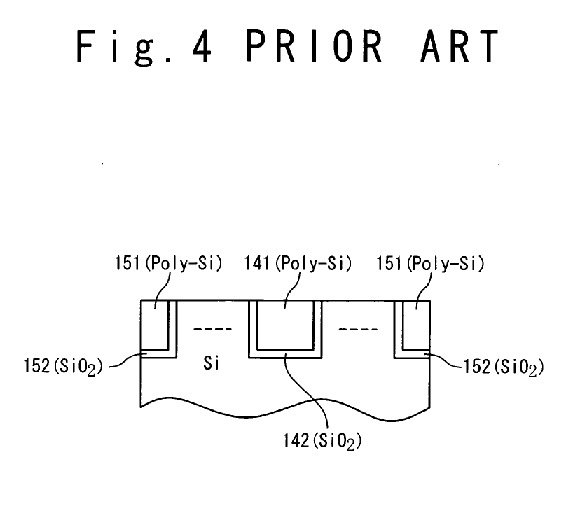

The manufacturing process of the MOS transistor shown in FIG. 6 will be described referring to FIGS. 7A-1 to 7E-2. FIGS. 7A-1 to 7E-1 show sectional views of the MOS transistor shown in FIG. 6 along the line X-X′, and FIGS. 7A-2 to 7E-2 show the sectional views of the MOS transistor along the line Y-Y′. A manufacturing process is divided into the first to fifth processes, and the respective sectional views at the time of completion of each step are shown in FIGS. 7A-1 and 7A-2, to 7E1 and 7E-2. Hereinafter, the manufacturing process of the NMOS transistor will be described as an example of the manufacturing process of the MOS transistor.

The sectional views at the time of completion of the first process are shown in FIGS. 7A-1 and 7A-2. In the first process, on the surface of a silicon substrate 30 of a first conductive type (for example, of a p-type conductive type), diffusion regions 31a, 31b, and 31c of a second conductive type (for example, an n-type conductive type) opposite to the first conductive type are formed. The diffusion regions 31a, 31b, and 31c are formed by ion implantation of ionized phosphorus (P), for example. Then, by using the mask 10 shown in FIG. 5A, patterning is performed on the semiconductor substrate, and a gate electrode trench 32 and the element isolating trench 33 are formed at a time through etching. The above-described patterning is preformed in a highly precise and high definition exposure, by using the highly precise mask 10. The gate electrode trench 32 and the element isolating trench 33 have substantially identical depth from the substrate surface such that the silicon substrate 30 is exposed on the surface of the substrate through the diffusion region.

FIGS. 7B-1 and 7B-2 show the sectional views after the completion of the second process. At the second process, a gate oxide film 34 such as SiO₂ is formed in the bottom and the side walls of the gate electrode trench 32 and the element isolating trench 33 which have been formed in the first process. Then, the gate electrode trench 32 and the element isolating trench 33 are filled with the gate electrode material such as polysilicon, which is used as a gate electrode 35 later. The excessive gate electrode material remaining on the surface of the substrate is removed after filling with the gate electrode material.

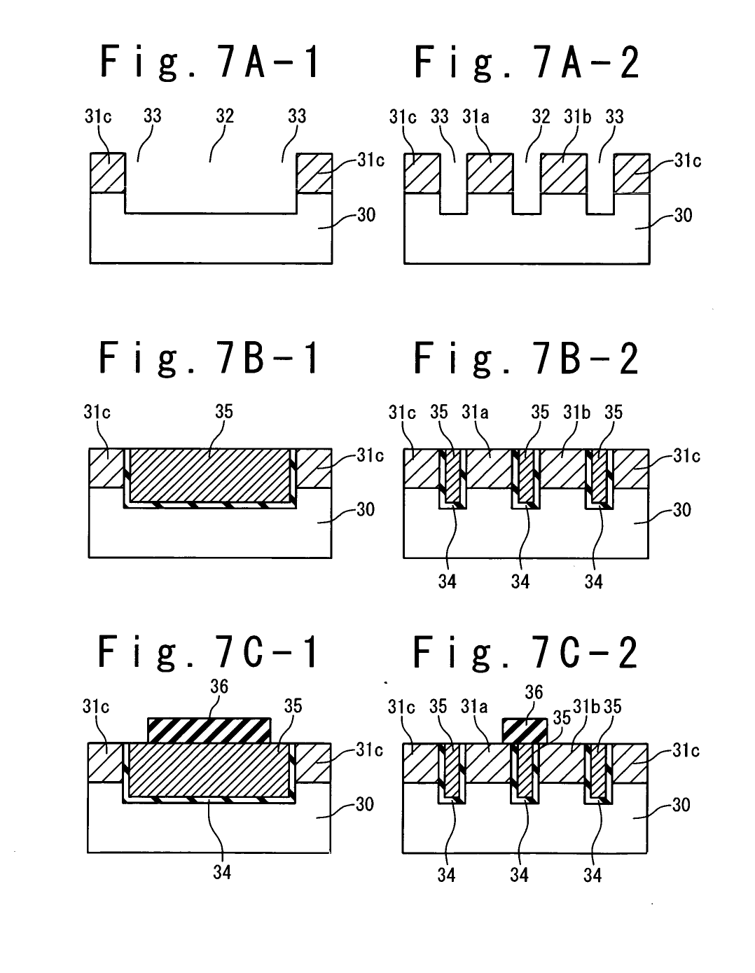

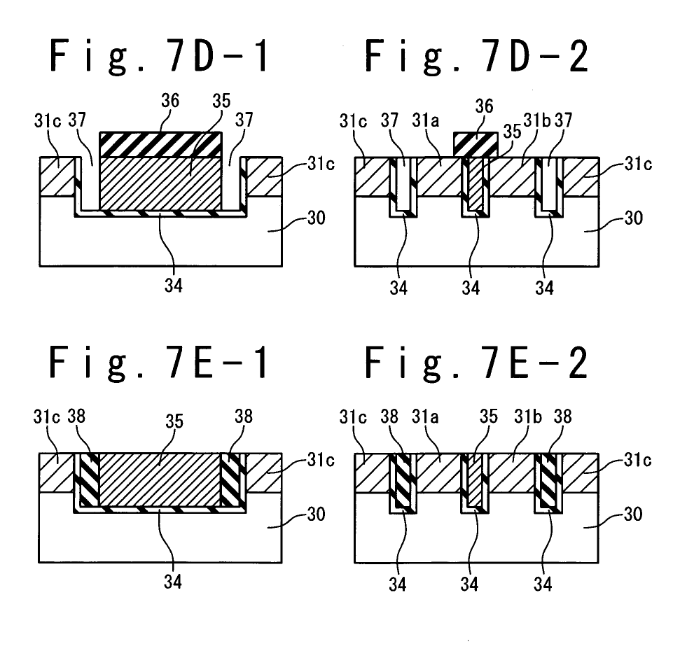

FIGS. 7C-a and 7C-2 show the sectional views after completion of the third process. In the third process, a resist pattern 36 is formed in a region where is larger than the gate electrode trench 32 in the direction of the line Y-Y′, on the substrate surface by using the mask 20 shown in FIG. 5B as a negative type resist mask. The mask 20 is a mask which is patterned in the pitch coarser than the mask 10. Therefore, when the resist pattern 36 is patterned, a resist layer may be exposed with preciseness and definition which is lower than in the patterning by using the mask 10. In the X-X′ section, the resist pattern 36 is formed in the region longer than the gate width W1 of the diffusion regions 31a and 31b. In the Y-Y′ section, the resist pattern 36 is formed in the region which covers the gate electrode 35 and a portion of the two diffusion regions 31a and 31b. That is, the length L2 of the resist pattern in the direction of gate length is longer than a distance L1 between the diffusion regions 31a and 31b. This resist pattern 36 protects the gate electrode material from etching in a subsequent process.

FIGS. 7D-1 and 7D-2 show the sectional views after completion of the fourth process. In the fourth process, the gate electrode material is removed by etching. Here, since the gate electrode material located under the resist pattern 36 is protected by the resist pattern 36 in the third process, it is not removed by etching. By this etching, the gate electrode material filling the element isolating trench is removed, and the element isolating trench 37 is formed. Further, the shape of the gate electrode material remaining after the etching is aligned with the shape of the gate electrode trench 32 formed on the substrate at the first process. By using the pattern formed on the substrate, the method of determining the shape of the region to be formed in the subsequent process as described above is called “self align”.

FIGS. 7E-1 and 7E-2 show the sectional views after completion of the fifth process. In the fifth process, the element isolating trench 37, which has been formed in the fourth process, is filled with an insulator such as an element isolating insulating film made of SiO₂, and an element separation region 38 is formed. Then, the excessive element isolating insulating film and the excessive resist pattern 36 on the surface of the substrate are removed. In this way, an NMOS transistor is completed.

In other words, in the semiconductor device of the present embodiment, by using the mask 10 having a fine pitch pattern, the gate electrode and the element isolating region is formed in a single etching process. The trench formed through the etching process is filled with the gate electrode material. Thereafter, a necessary gate electrode region is protected from etching by using a resist pattern longer than the gate electrode. Then, the gate electrode material of a portion which is not covered with the resist pattern is removed. In this way, a highly precise gate electrode is formed. Here, the gate width and the gate length, which are important in the shape of the gate electrode, are defined in self alignment according to the shape of the portion between the element isolating regions separately formed each other. Therefore, even when the mask 20 having a coarse pitch pattern is used, the gate electrode required for operation of a transistor can be formed with the sufficient accuracy. In the semiconductor device according to the present embodiment, it is possible to form the MOS transistor and the gate electrode 35 defined in the fine pitch, while reducing the number of times of the highly precise and high definition exposure process and the number of masks having the highly precise pattern.

On the other hand, in the semiconductor device of the conventional example, the element isolating region had to be formed by using a mask having the fine pitch pattern, and the gate electrode had to be formed by using a mask having the fine pitch pattern.

From the above description, since the semiconductor device of the present embodiment can reduce the masks having a highly precise pattern and the number of times of highly precise and high definition exposure process, it can reduce the time and cost for forming the masks and a manufacturing process thereof.

The semiconductor device of the present embodiment is formed such that the width of the gate electrode 35 will be longer than the width of the diffusion regions 31a and 31b. The both ends of the gate electrode 35 in the direction of the gate length are formed to be longer than the length L1 between the two diffusion regions 31a and 31b. From this, the gate electrode 35 of the first embodiment, even when the end portions are removed through the etching, it is possible to suppress an etching damage to the gate electrode material in the region serving as a gate in a transistor operation. It is particularly advantageous to suppress the etching damage in order to control variation in the manufacturing process in case of forming the fine pattern.

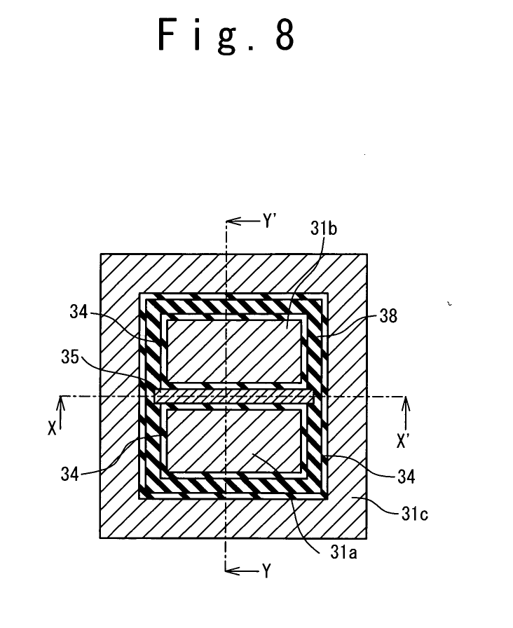

It should be noted that in the above-described first embodiment, the both end of the gate electrode 35 along the gate width direction are formed as T-shaped. However, the shape of both ends is not restricted to this. For example, the length the gate electrode 35 in the direction of the gate length at the both end portions may be substantially same as or shorter than the length between the diffusion regions 31a and 31b in the direction of the gate length. A semiconductor device where the length of the gate electrode 35 at the both end portions is same as that of remaining portion of the gate electrode 35 is shown in FIG. 8. Here, in the semiconductor device shown in FIG. 8, the diffusion region 31a and 31b are formed in adjacent to the element isolating region 38 through the gate oxide film 34 in the whole sides other than the sides of the diffusion region 31a and 31b opposite to each other. On the other hand, in the semiconductor device shown in FIG. 6, the diffusion regions 31a and 31b are formed in adjacent to on the element isolating region 38 through the gate oxide film 34 in a portion of the sides other than the sides of the diffusion regions 31a and 31b opposite to each other. Here, in the semiconductor device shown in FIGS. 6 and 8, the diffusion regions 31a and 31b, and the element isolating region 38 may be formed without interposing the gate oxide film 34.

### Second Embodiment

The semiconductor device according to the second embodiment of the present invention has the same shape as the MOS transistor formed in the first embodiment, by using the same masks. However, the manufacturing method thereof is different. The semiconductor device in the first embodiment forms the element separation region 38 by an element isolating insulating film after forming gate electrode 35. On the other hand, the semiconductor device according to the second embodiment forms the element separation region 38 by an element isolating insulating film, and then, the gate electrode 35 is formed. The same components as in the first embodiment are assigned with the same numerals and the description is omitted.

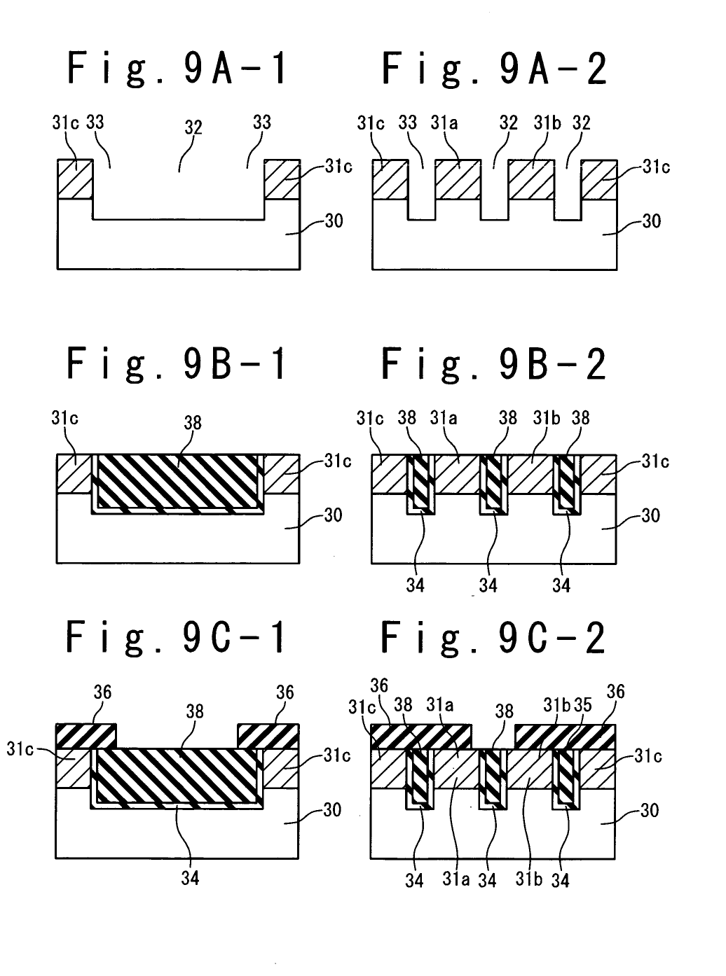

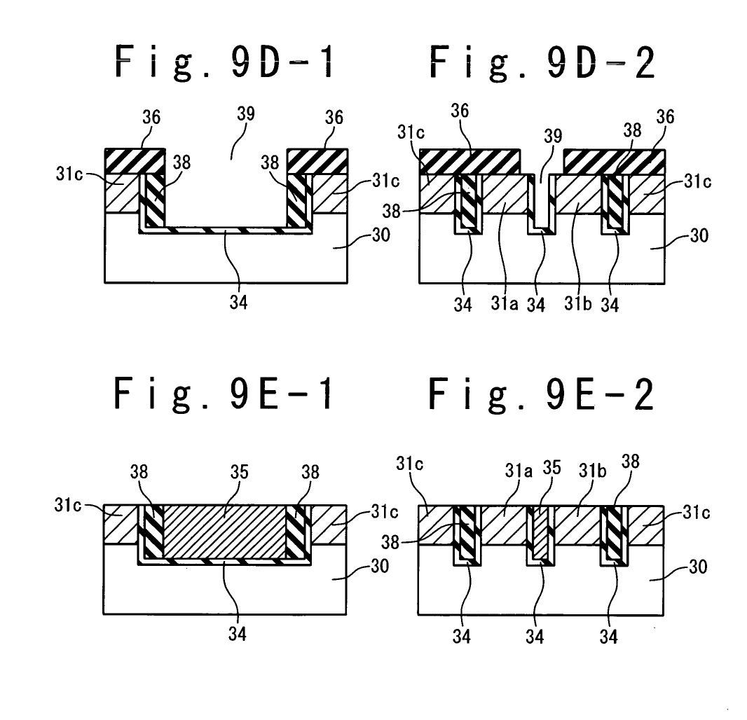

The manufacturing process of the MOS transistor in the second embodiment is described with reference to FIGS. 9A-1 to 9E-2. FIGS. 9A-1 to 9E-1 show the sectional views along the line X-X′ of the MOS transistor shown in FIG. 6, and FIGS. 9a-2 to 9E-2 show the sectional views along the line Y-Y′. A manufacturing process is divided into the first to fifth processes, and the respective sectional views at the time of completion of each step are shown in FIGS. 9A-1 to 9E-2. Hereinafter, the manufacturing process of the NMOS transistor will be described as an example of the manufacturing process of the MOS transistor.

The sectional views at the time of completion of the first process are shown in FIG. 9A-1 and 9A-2. In the first process, on the surface of a silicon substrate 30 having a first conductive type such as a p-type conductive type, the diffusion regions 31a, 31b, and 31c having a second conductive type such as an n-type conductive type are formed, which is opposite to the first conductive type. The diffusion regions 31a, 31b, and 31c are formed by ion implantation of ionized phosphorus (P), for example. Then, by using the mask 10 shown in FIG. 5A, patterning is performed on the semiconductor substrate, to form the gate electrode trench 32 and the element isolating trench 33 through etching at a time. The above-described patterning is performed in the highly precise and high definition exposure, by using the highly precise mask 10. The gate electrode trench 32 and the element isolating trench 33 have substantially a same depth from the substrate surface such that the silicon substrate 30 is exposed on the surface of the substrate through the diffusion region.

FIGS. 9B-1 and 9B-2 show the sectional views after the completion of the second process. At the second process, the gate oxide film 34 such as SiO₂ is formed in the bottoms and the side walls of the gate electrode trench 32 and the element isolating trench 33 which have been formed in the first process. Subsequently, the gate electrode trench 32 and the element isolating trench 33 are filled with insulator such as an element isolating insulating film formed of SiO₂ which is used as the element isolating region 38 later. The excessive element isolating insulating film remaining on the surface of the substrate is removed after filling with the element isolating insulating film.

FIGS. 9C-1 and 9C-2 show the sectional views after completion of the third process. In the third process, the resist pattern 36 is formed in the region other than the periphery of the gate electrode trench 32 on the substrate surface by using the mask 20 shown in FIG. 5B as a positive type resist mask. The mask 20 is a mask which is patterned in the pitch coarser than the mask 10. Therefore, when patterning the resist pattern 36, it can be exposed in preciseness and definition which is lower than the patterning by using the mask 10. The resist pattern 36 has an opening so that a part of the substrate surface is exposed. In the X-X′ section, the opening is formed so that the region larger than the gate width W1 of the diffusion regions 31a and 31b is exposed. In the Y-Y′ section, the opening is formed in a region where the gate electrode trench 32 and a region between the two diffusion regions 31a and 31b. That is, the length L2 of the portion in which the substrate surface is exposed in the direction of gate length is longer than the distance L1 between the diffusion regions 31a and 31b. This resist pattern 36 protects the element isolating region 38 from etching to be performed in a subsequent process.

FIGS. 9D-1 and 9D-2 show the sectional views after completion of the fourth process. In the fourth process, the element isolating insulating film of the portion where the gate electrode material is embedded is removed by etching. Here, since the element isolating insulating film under the resist pattern 36 formed at the third process is protected by the resist pattern 36, it is not removed through etching. By this etching, the element isolating insulating film filling the gate electrode trench 32 is partially removed, and the gate electrode trench 39 is formed. Further, the shape of the gate electrode trench 39 formed by etching is aligned with the shape of the gate electrode trench 32 formed on the substrate in the first process. By using the pattern formed on the substrate, the method of determining the shape of the region formed in the subsequent process as described above is called “self align”.

FIGS. 9E-1 and 9E-2 show the sectional views after completion of the fifth process. In the fifth process, the gate electrode trench 39, which has been formed in the fourth process, is filled with the gate electrode material, and the gate electrode 35 is formed. Subsequently, the excessive gate electrode material and the excessive resist pattern 36 on the surface of the substrate are removed. In this way, the NMOS transistor is completed.

That is, in the semiconductor device according to the second embodiment, the gate electrode and the element isolating region are formed in a single etching process by using the mask 10 having a fine pitch pattern. The trench formed by the etching process is filled with the element isolating insulating film. Subsequently, the element isolating insulating film in the gate electrode region is removed by etching by using a resist pattern larger than the gate electrode. Then, the gate electrode material fills the gate electrode trench formed by etching to form the gate electrode. In this way, a highly precise gate electrode is formed similar to the first embodiment.

From the above description, in the semiconductor device according to the second embodiment, since the semiconductor device can reduce the mask having a highly precise pattern and the number of times of highly precise and high definition exposure process, it can reduce the time and cost for forming the masks and the manufacturing process thereof.

Further, the number of steps which are performed after forming the gate electrode is reduced as compared with the first embodiment. Therefore, the influence of the stress to the gate electrode added in the steps and accumulation of the heat history to the gate electrode can be suppressed. Generally, when forming the gate electrode, a gate electrode is formed to be thicker than an original gate electrode, in consideration of the influence of the heat history and/or the stress. However, in the semiconductor device of the second embodiment, since the influence of the heat history and/or the stress can be reduced, it is not necessary to have a margin required in the conventional example. Therefore, according to the semiconductor device of the second embodiment, it is possible to form a fine gate electrode having higher-precision than the semiconductor device in the first embodiment. Further, in the semiconductor device in the second embodiment, an etching process after the formation of the gate electrode is eliminated. Therefore, the formed gate electrode does not receive the damage from etching.

### Third Embodiment

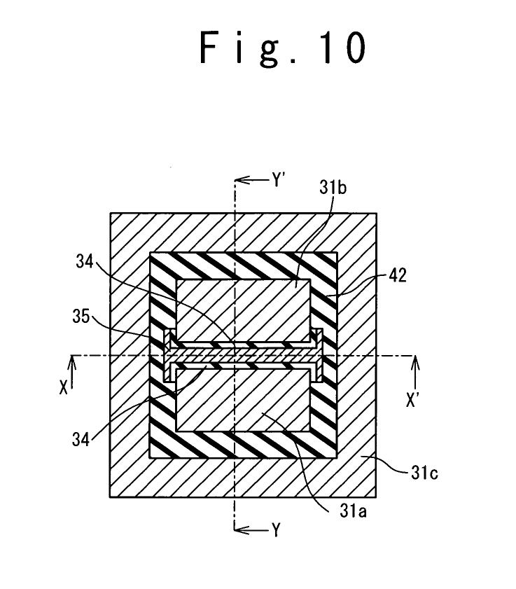

FIG. 10 shows a layout of the MOS transistor according to the third embodiment of the present invention. In the MOS transistor according to the third embodiment, substantially the same masks as those used in the first embodiment are used. However, as shown in FIG. 10, the MOS transistor in the third embodiment differs from the MOS transistor in the first embodiment in the point that the gate oxide film 34 is not provided on the outer periphery of the element isolating region 42, and the outer periphery of the diffusion regions 31a and 31b. It should be noted that in the MOS transistor according to the third embodiment, the gate electrode 35 and the diffusion regions 31a and 31b are contact with through the gate oxide film 34.

The manufacturing process of the MOS transistor shown in FIG. 10 will be described with reference to FIGS. 11A-1 to 11E-2. FIGS. 11A-1 to 11E-1 show the sectional views of the MOS transistor shown in FIG. 10 along the line X-X′, and, in the right side, FIGS. 11A-2 to 11E-2 show the sectional views of the same along the line Y-Y′. A manufacturing process is divided into the first to fifth processes, and the respective sectional views at the time of completion of each step are shown in FIGS. 11A-1 to 11E-2. Hereinafter, the manufacturing process of an NMOS transistor is explained as an example of the manufacturing process of an MOS transistor.

The sectional views at the time of completion of the first process are shown in FIGS. 11A-1 and 11A-2. In the first process, on the surface of the silicon substrates 30, which is a p-type conductive type, the diffusion regions 31a, 31b, and 31c are formed, which is an n-type conductive type. The diffusion regions 31a, 31b, and 31c are formed by ion implantation of ionized phosphorus (P), for example. Further, a hard mask material 40 such as silicon nitride (SiN) is formed on the surface of the diffusion regions 31a, 31b, and 31c. Subsequently, by using the mask 10 shown in FIG. 5A, patterning is performed on the semiconductor substrate, to form the gate electrode trench 32 and the element isolating trench 33 through etching at a time. The above patterning is performed in highly precise and high definition exposure, by using the highly precise mask 10. The gate electrode trench 32 and the element isolating trench have a same depth from the surface of the hard mask material 40 such that the silicon substrate 30 is exposed on the surface of the hard mask through the diffusion regions.

FIGS. 11B-1 and 11B-2 show the sectional views after the completion of the second process. In the second process, the gate oxide film 34 formed of SiO₂, for example is formed in the bottoms and the side walls of the gate electrode trench 32 and the element isolating trench 33 which have been formed in the first process. Then, the gate electrode trench 32 and the element isolating trench 33 are filled with the gate electrode material such as polysilicon which is used as the gate electrode 35 later. The excessive gate electrode material remaining on the surface of the hard mask material 40 is removed after filling with the gate electrode material.

FIGS. 11C-1 and 11C-2 show the sectional views after completion of the third process. In the third process, the resist pattern 36 is formed in the region, which is larger than the gate electrode trench 32 in the direction of the line Y-Y′, on the substrate surface by using the mask 20 shown in FIG. 5B. The mask 20 is a mask which is patterned in the pitch coarser than the mask 10. Therefore, when patterning the resist pattern 36, it can be exposed in preciseness and definition which is lower than the patterning by using the mask 10. In the X-X′ section, the resist pattern 36 is formed in the region wider than the gate width W1 of the diffusion regions 31a and 31b. In the Y-Y′ section, the resist pattern 36 is formed in a region which covers the gate electrode 35 and a region between the two diffusion regions 31a and 31b. That is, the length L2 of the resist pattern in the direction of gate length is longer than the distance L1 between the diffusion regions 31a and 31b. This resist pattern 36 protects the gate electrode material from the etching to be performed in the subsequent process.

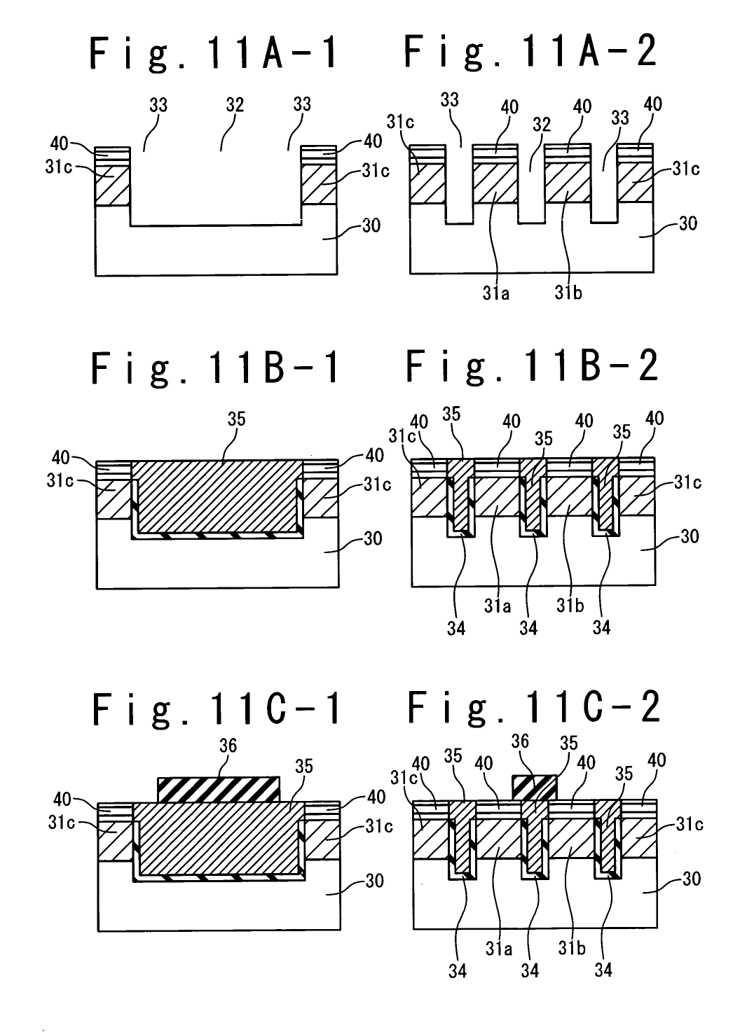

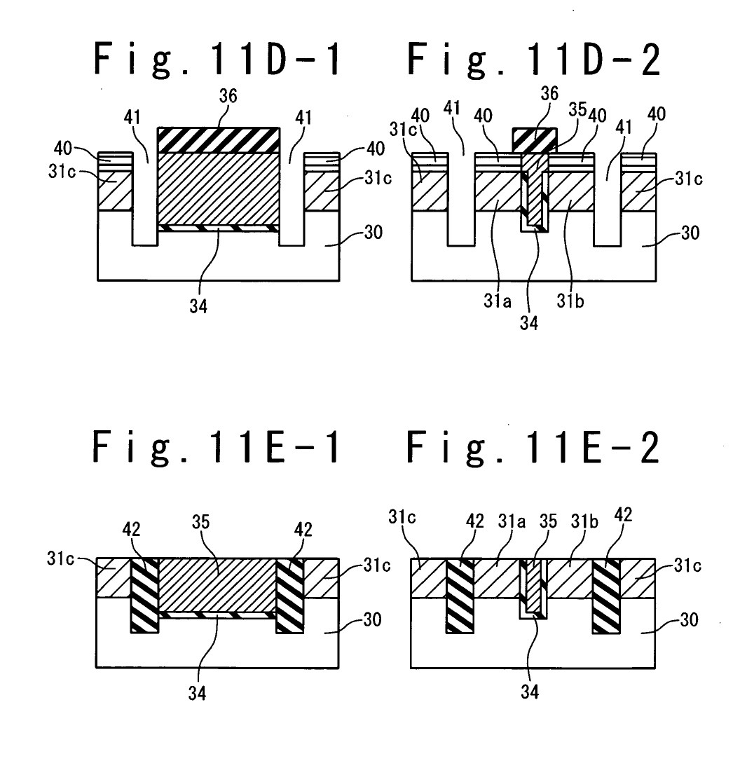

FIGS. 11D-1 and 11D2 show the sectional views after completion of the fourth process. In the fourth process, the gate oxide film 34 and the gate electrode material which are not covered by the resist pattern 36 are removed by etching. Here, since the gate electrode material under the resist pattern 36 is protected by the resist pattern 36 in the third process, it is not removed by etching. By this etching, the gate electrode material filling the element isolating trench and the gate oxide film 34 are removed, and the element isolating trench 41 is formed. The bottom of the element isolating trench 41 is formed in a region deeper than the bottom of the gate electrode trench 32. Further, the shape of the gate electrode material remaining after the etching is aligned with the shape of the gate electrode trench 32 formed on the substrate at the first process.

FIGS. 11E-1 and 11E-2 show the sectional views after completion of the fifth process. In the fifth process, the element isolating trench 41, which has been formed in the fourth process, is filled with an element isolating insulating film such as a SiO₂ film, and the element separation region 42 is formed. Then, the excessive element isolating insulating film, the resist pattern 36, and the hard mask material 40 on the surface of the substrate are removed. In this way, the NMOS transistor is completed.

From the above description, in the MOS transistor according to the third embodiment, the bottom of the element isolating region 42 can be formed in the deeper region as compared to the first embodiment, by protecting the substrate surface with the resist pattern 36 and the hard mask material 40. Thus, since the MOS transistor of the third embodiment can improve its electrical element isolating as compared with the MOS transistor according to the first embodiment, it can improve withstand voltage.

### Fourth Embodiment

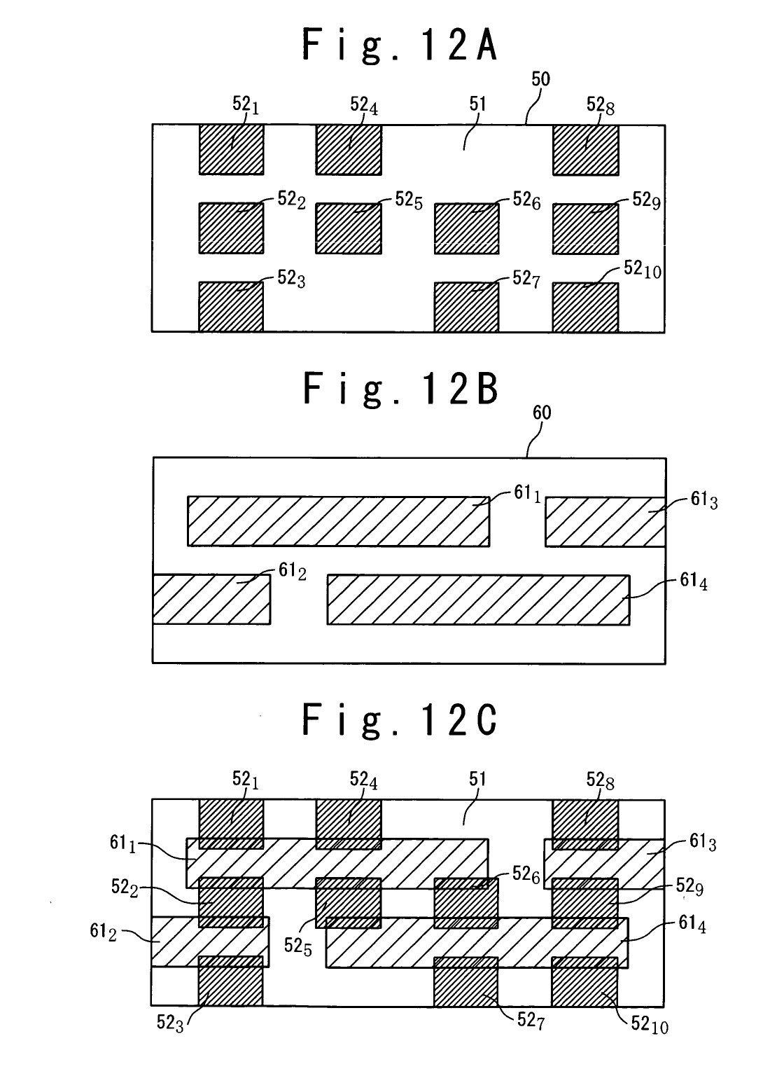

In the fourth embodiment, the transistor according to the third embodiment is applied to a memory cell of an SRAM (Static Random Access Memory) as an example of a circuit employing a plurality of transistors according to the third embodiment. The masks used in forming the SRAM memory cell according to the fourth embodiment are shown in FIGS. 12A and 12B.

A mask 50 shown in FIG. 12A is a mask having a pitch pattern finer than that of other masks, and including trench region patterns 51 and diffusion region patterns 52₁ to 52₁₀. A mask 60 shown in FIG. 12B is a mask which has a pitch pattern coarser than that of the mask 50, and including gate region patterns 61₁ to 61₄. A mask layout in which the mask 50 shown in FIG. 12A and the mask 60 shown in FIG. 12B are overlapped is shown in FIG. 12C. As shown in FIG. 12C, each of the gate region patterns 61₁ to 61₄ is formed such that it covers a part of the opposing two diffusion regions located in the up-and-down direction in FIG. 12C.

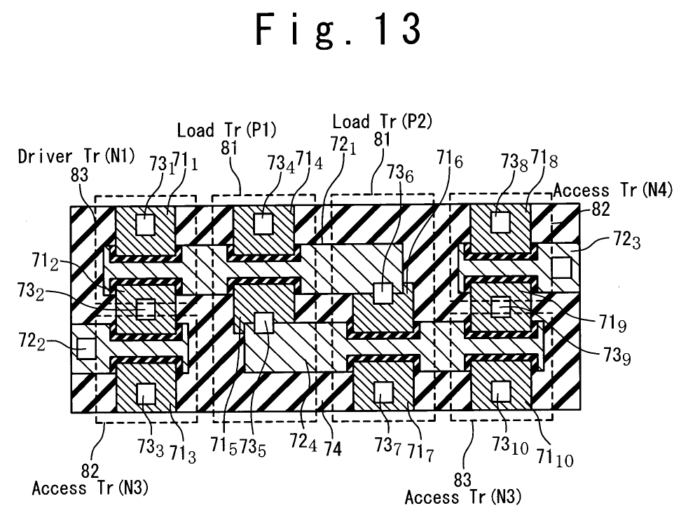

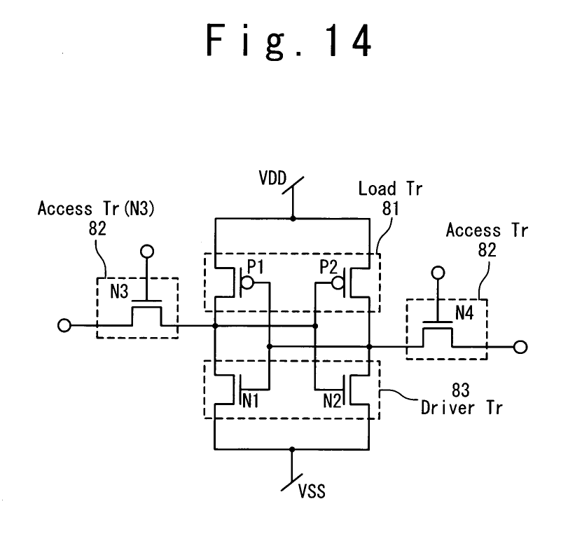

FIG. 13 is a top view showing a layout of the SRAM memory cells formed by using the masks 50 and 60. Here, in the layout shown in FIG. 13, the wiring on the upper layer of the substrate is not shown.

As shown in FIG. 13, the SRAM memory cells include diffusion regions 71₁ to 71₁₀ and gate electrodes 72₁ to 72₄. The diffusion region 71₁ to 71₁₀ have contacts 73₁ to 73₁₀ which connect the wiring line in the upper layer and the diffusion region, respectively. The gate electrode 72₁ is formed in the region adjacent to the diffusion regions 71₁, 71₂, 71₄, 71₅, and 71₆. In the gate electrode 72₁, the region where the diffusion regions 71₁ and 71₂ oppose to each other and the region where the diffusion regions 71₄ and 71₅ oppose to each other are thinner than the other portions. The gate electrode 72₂ is formed such that it abuts on the diffusion regions 71₂ and 71₃. Further, in the gate electrode 72₂, the portion where the diffusion regions 71₂ and 71₃ oppose to each other are thinner than the other portions.

The gate electrode 72₃ is formed such that it contact with on the diffusion regions 71₈ and 71₉. In the gate electrode 72₃, the portion where the diffusion regions 71₈ and 71₉ oppose to each other is thinner than the other portions. The gate electrode 72₄ is formed in the region which is adjacent to the diffusion regions 71₅, 71₆, 71₇, 71₉, and 71₁₀. Further, in the gate electrode 72₄, the region where the diffusion region 71₆ and 71₇ oppose to each other and the region where the diffusion 71₉ and 71₁₀ oppose to each other are thinner than the other portions.

The circuit diagram of the SRAM memory cell shown in FIG. 13 is shown in FIG. 14. The SRAM memory cell circuit shown in FIG. 14 has load transistors P1 and P2, driver transistors N1 and N2, and access transistors N3 and N4. The load transistor P1 and the driver transistor N1 are connected in series between the power supply voltage VDD and the grounding voltage VSS. The load transistor P2 and the driver transistor N2 are connected in series between the power supply voltage VDD and the grounding voltage VSS. The gate of the access transistor N3 is connected to the word line (not shown), one terminal thereof is connected to a bit line (not shown), and the other terminal is connected to a contact, which is a contact for the drain of the load transistor P1 and the drain of the driver transistor N1, and the gates of the load transistor P2 and the driver transistor N2. The gate of the access transistor N4 is connected to the word line (not shown), and one terminal thereof is connected to a bit line (not shown), and the other terminal is connected to a contact. The contact is to connect the drain of the load transistor P2 and the drain of the driver transistor N2, and the gates of the load transistor P1 and the driver transistor N1.

In the layout shown in FIG. 13 and the circuit diagram shown in FIG. 14, correspondence relations are described hereinafter. The driver transistor N1 is formed by the diffusion regions 71₁ and 71₂ and the gate electrode 72₁ which is adjacent to the diffusion regions 71₁ and 71₂. The load transistor P1 is formed by the diffusion regions 71₄ and 71₅ and the gate electrode 72₁ which is adjacent to the diffusion regions 71₄ and 71₅. The access transistor N3 is formed by the diffusion regions 71₂ and 71₃ and the gate electrode 72₂ which is adjacent to the diffusion regions 71₂ and 71₃. The driver transistor N2 is formed by the diffusion regions 71₉ and 71₁₀ and the gate electrode 72₄ which is adjacent to the diffusion regions 71₉ and 71₁₀. The load transistor P2 is formed by the diffusion regions 71₆ and 71₇ and the gate electrode 72₄ which is adjacent to the diffusion regions 71₆ and 71₇. The access transistor N4 is formed by the diffusion regions 71₈ and 71₉ and the gate electrode 72₃ which is adjacent to the diffusion regions 71₈ and 71₉.

As described above, it is possible to constitute a SRAM memory cell by using the transistor according to the third embodiment. Thus, it is possible to simplify the manufacturing process and to reduce a production time and a manufacturing cost as compared with the conventional example, by combining the mask 50 having a fine pitch pattern and the mask 60 having a coarse pitch pattern, even in the circuit which requires the patterning by the precise pattern.

In addition, the present invention should not be restricted to the above-described embodiment, rather, it can be suitably altered within the scope of the present invention. For example, the present invention can be applied to a circuit other than an SRAM as far as the circuit employs an element which is formed by the fine pattern.

What is claimed is:

1. A semiconductor device having a source and a drain, said device comprising:
first and second regions as said source and said drain, respectively; and
a gate electrode formed to have a buried gate structure, a portion of said gate electrode being put between said first and second regions,
wherein a width of said gate electrode is wider than a gate width of said first and second regions.

2. The semiconductor device according to claim 1, wherein said gate electrode has a third portion which is not put between said first and second regions, and
a gate length between said first and second regions is shorter than a length of said third portion in a gate length direction.

3. The semiconductor device according to claim 1, wherein said gate electrode has a third portion which is not put between said first and second regions, and
two ends of said third portion are provided for ends in a gate width direction.

4. The semiconductor device according to claim 1, wherein each of said first and second regions is contact with an element separation region at a part of sides other than a side opposite to a side of the other.

5. The semiconductor device according to claim 1, wherein each of said first and second regions is contact with an element separation region at a whole of sides other than a side opposite to a side of the other.

6. The semiconductor device according to claim 2, wherein said elements are arranged, and
said gate electrode is common to said elements and has said third portion length between said elements.

7. The semiconductor device according to claim 1, wherein a depth of said element separation region is substantially a same as that of said gate electrode.

8. The semiconductor device according to claim 1, wherein a depth of said element separation region is deeper than that of said gate electrode.

9. A method of manufacturing a semiconductor device, comprising:
forming a conductive region on a semiconductor substrate;
performing a first patterning to said conductive layer and said semiconductor substrate by using a first mask to form a gate electrode trench, a device separation trench, and first and second regions;
filling said gate electrode trench and said device separation trench with a gate electrode material;
forming a resist pattern by using a second mask having a pattern coarser than said first mask;
removing said gate electrode material from a part of said gate electrode trench and said device separation trench by said resist pattern; and
filing said gate electrode trench part and said device separation trench with an insulating film to form a device separation region.

10. The method of manufacturing a semiconductor device according to claim 9, wherein a width of said gate electrode is wider than a width of said first and second regions in a gate width direction.

11. The method of manufacturing a semiconductor device according to claim 9, wherein a gate length between said first and second regions is shorter than a length of a third portion of said gate electrode which is not put between said first and second regions, in a gate length direction.

12. The method of manufacturing a semiconductor device according to claim 9, wherein a depth of said device separation region is substantially a same as that of said gate electrode.

13. The method of manufacturing a semiconductor device according to claim 9, wherein a depth of said device separation region is deeper than that of said gate electrode.

14. The method of manufacturing a semiconductor device according to claim 9, further comprising:
before filling said gate electrode material into said gate electrode trench and said device separation trench, forming a gate oxide film on a bottom and side wall of said gate electrode trench and said device separation trench.

15. A method of manufacturing a semiconductor device, comprising:
forming a conductive region on a semiconductor substrate;
performing a first patterning to said conductive layer and said semiconductor substrate by using a first mask to form a gate electrode trench, a device separation trench, and first and second regions;
filling said gate electrode trench and said device separation trench with an insulating film to form a device separation region;
forming a resist pattern by using a second mask having a pattern coarser than said first mask, to expose a part of said gate electrode trench and a periphery of said gate electrode trench;
removing said insulating film from a region not covered by said resist pattern; and
filling a gate electrode material in a region from which said insulating film is removed, to form a gate electrode.

16. The method of manufacturing a semiconductor device according to claim 15, wherein a width of said gate electrode is wider than a width of said first and second regions in a gate width direction.

17. The method of manufacturing a semiconductor device according to claim 15, wherein a gate length between said first and second regions is shorter than a length of a third portion of said gate electrode which is not put between said first and second regions, in a gate length direction.

18. The method of manufacturing a semiconductor device according to claim 15, wherein a depth of said device separation region is substantially a same as that of said gate electrode.

19. The method of manufacturing a semiconductor device according to claim 15, wherein a depth of said device separation region is deeper than that of said gate electrode.

20. The method of manufacturing a semiconductor device according to claim 15, further comprising:
before filling said gate electrode material into said gate electrode trench and said device separation trench, forming a gate oxide film on a bottom and side wall of said gate electrode trench and said device separation trench.
